(19) United States
(12) Patent Application Publication
(10) Pub. No.: US 2005/0181618 A1
(43) Pub. Date: Aug. 18, 2005

(54) Polymer via etching process

(75) Inventors: Jennifer Wang, Redondo Beach, CA (US); Mike Barsky, Sherman Oaks, CA (US)

Correspondence Address: LaRiviere, Grubman & Payne, LLP, P.O. Box 3140, Monterey, CA, 93942, US

(73) Assignee: Northrop Grumman Space & Mission Systems Corporation, Redondo Beach, CA (US)

(21) Appl. No.: 10/781,353

(22) Filed: Feb. 17, 2004

(51) Int. Cl. H01L 21/4763; H01L 21/302; H01L 21/44; H01L 21/461

(52) U.S. Cl. 438/725; 438/713; 438/714

(57) ABSTRACT

An improved etching process for creating dimensionally accurate sub-micron and micron via-openings is disclosed. Specifically, this invention discloses a via etching process for a polymer layer (24) deposited on a semiconductor substrate (28) comprising the steps of: placing the semiconductor substrate comprising a polymer layer (24) deposited on the semiconductor substrate, a hard-mask (30) deposited on the polymer layer (24) and a photoresist mask (32) deposited on the hard-mask (30). The invention further, discloses performing a hard-mask opening step (34) comprising releasing a first fluoride gas (36) into the chamber. Furthermore, performing a polymer etching step (40) comprising releasing a second fluoride gas (42) into the chamber is disclosed. The invention also includes a hard-mask removal and tapered via step (46) to increase process margin.

### TECHNICAL FIELD

This invention relates to an dry etching process for semiconductor substrates. More particularly, the present invention relates to a polymer dry etching process that produces smaller dimensionally accurate via holes for a thick polymer layer in a semiconductor substrate while maintaining adjacent device features and reducing semiconductor wafer substrate cycle time through the reduction of processing steps.

### BACKGROUND ART

Semiconductor technology is producing smaller device features, on the order of a micron and or a sub-micron. To accurately reproduce micron or sub-micron features, presently available dry etching processes need to be revised. The prior art etching process using a photoresist mask for pattern transfer results in limiting of the polymer etching depth, for example, a via-opening on a semiconductor substrate.

FIGS. 1A and 1B are prior art etching process flow diagrams for creating a via-opening in a semiconductor substrate. As shown in FIG. 1A, an insulating film 12 is deposited on a GaAs semiconductor substrate 14. Afterwards, a first resist mask 16 is coated on the insulating film 12 and is patterned during exposure to ultraviolet light. Following, as shown in FIG. 1B, GaAs semiconductor substrate 14 including insulating film 12 and a first resist layer 16 are etched removing first resist mask 16 defining a via-opening 18. In this step, the thickness of first resist mask 16 is limited by the present limitations of photoresist thickness technology because a thicker resist mask, i.e., in the order of several micron range, will limit the minimum via hole feature size that can be accurately registered on a semiconductor substrate. In addition, because the selectivity of a first resist mask 16 is poor compared to insulating film 12, the polymer hole depth is limited to keep the aspect ratio of the depth of the opening to the width of the opening less than one. In other words, during the first etching process, etching of a polymer hole depth less than the width of the via-opening will cause a significant increase in the via hole width, resulting in overlapping vias, and damaging adjacent device features such as resistors, capacitive layers, other via holes, or other transistor layers.

Therefore, it is extremely difficult to etch the required polymer layer depth. As such, it would be beneficial to develop a new dry etching process to create deeper via holes, i.e, a few microns deep, for smaller width via-openings without purchasing another photoresist mask set which may be expensive. Furthermore, for sub-micron width vias, there is a need to increase the process margin for subsequent semiconductor processing steps. One method to increase the process margin is to create a tapered via-opening for better metal-filling. FIG. 1C is a prior art via structure showing a via hole before hard mask removal. FIG. 1D shows the prior art via structure after hard mask removal. As shown in FIG. 1D, the corners of insulating layer 21 are sharp and not tapered. As such, there is a need for a single via etching process that produces tapered sidewalls and removes the hard mask layer without the need for additional photoresist and wet chemical etching steps.

In summary, there is a need for an improved etching process including improved etching selectivity to achieve dimensionally accurate sub-micron via-openings and to provide other advantages over the prior art etching processes. Some of the other advantages include creating dimensionally accurate via holes and via hole sidewalls proximal to the top of a sub-micron via hole, and reducing wafer cycle time so that there are fewer required steps. Other advantages include creating an etching process that minimizes hazardous waste disposal issues and that can be more precisely controlled or monitored by a semiconductor engineer and will be easier to transfer to production. Furthermore, this process should produce greater process margin for sub-micron via holes, such creating a tapered via-opening for subsequent processing steps. Still another advantage of this etching process is that the hard mask etch rate occurs at an extremely slow rate while the via-opening etch rate is extremely fast.

### DISCLOSURE OF THE INVENTION

Accordingly, the present invention provides an improved etching process for creating dimensionally accurate micron and sub-micron via-openings. As disclosed, the present invention provides an improved via etching process that prevents adjacent devices from being etched. In one embodiment, the etching process is utilized for via-hole processing. As disclosed, the present invention is a via etching process for a polymer layer deposited on a semiconductor substrate comprising the steps of depositing a polymer layer on the semiconductor substrate, depositing a hard-mask on the polymer layer, and depositing a photoresist mask on the hard-mask.

In this embodiment, the first fluoride gas comprises trifluoromethane (CHF₃) and argon (Ar). The first fluoride gas comprises equal amounts of trifluoromethane (CHF₃) and argon (Ar). Additionally, in this embodiment, the hard-mask opening step further comprises applying bias power and pulse modulated power. The hard-mask opening step continues for a time in a range of three to five minutes. Afterwards, a second fluoride gas comprising Sulfur Hexafluoride (SF₆) and Oxygen (O₂) is released in the chamber to complete the creation of a vertical side wall via.

In another embodiment, a via etching process for a polymer layer on a semiconductor substrate comprising the steps of: depositing a polymer layer defining a sub-micron wide via-opening on the semiconductor substrate, and depositing a hard-mask defining the sub-micron wide via-opening on the polymer layer. In this embodiment, performing a hard-mask removal and tapered via etching step comprising: releasing a third fluoride gas into the chamber, whereby the hard-mask is etched away, and whereby an exposed portion of the polymer layer proximal to the sub-micron wide via-opening is etched away to create tapered sidewalls. In the second embodiment, the third fluoride gas comprises trifluoromethane (CHF₃) and argon (Ar). In yet one alternative of this embodiment, the third fluoride gas comprises equal amounts of trifluoromethane (CHF₃) and argon (Ar).

### BRIEF DESCRIPTION OF THE DRAWINGS

For a better understanding of the present invention, reference is made to the below-referenced accompanying drawings. Reference numbers refer to the same or equivalent parts of the present invention throughout the several figures of the drawings.

FIG. 1A is a section view of a prior art semiconductor structure.

FIG. 1B is a section view of a prior art semiconductor structure.

FIG. 1C is a section view of a prior art semiconductor structure.

FIG. 1D is a section view of a prior art semiconductor structure.

FIG. 2A is a section view of a semiconductor structure before the first etching step of the present invention.

FIG. 2B is a section view of a semiconductor structure after the first etching step of the present invention.

FIG. 2C is a section view of a semiconductor structure after the second etching step of the present invention.

FIG. 3 is a section view of the present invention of the semiconductor structure made by the first and second etching steps that create a via-opening in a polymer layer with vertical sidewalls.

FIG. 4A is a section view of a semiconductor structure of a second embodiment of the present invention before the third etching step.

FIG. 4B is a section view of a semiconductor structure of a second embodiment of the present invention after the third etching step.

FIG. 5 is a section view of the present invention of the semiconductor structure made using the third etching process that creates a tapered via-hole.

FIG. 6 is a flow chart of the polymer via etching process of the present invention.

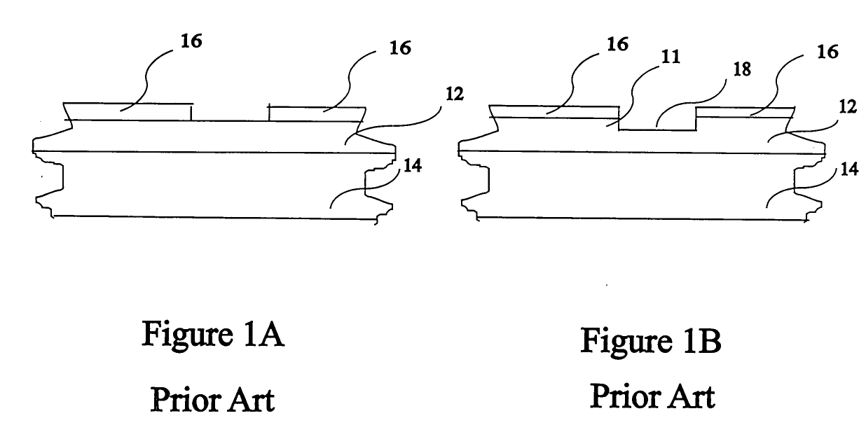

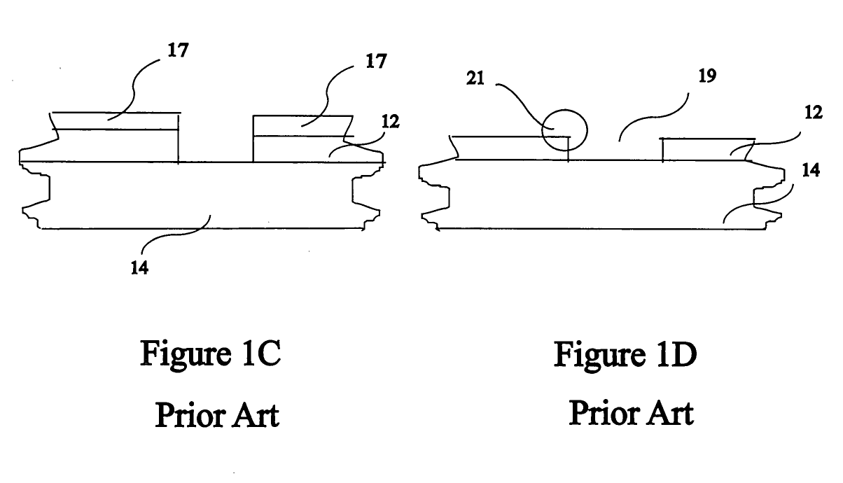

### MODES FOR CARRYING-OUT THE INVENTION

The present invention is directed for creating a via-opening within a semiconductor wafer. Accordingly, the present invention provides an improved etching process for creating dimensionally accurate micron and sub-micron via-openings. As disclosed, the present invention provides an improved via etching process that prevents adjacent devices from being etched. In one embodiment, the dry etching process is utilized for via hole processing.

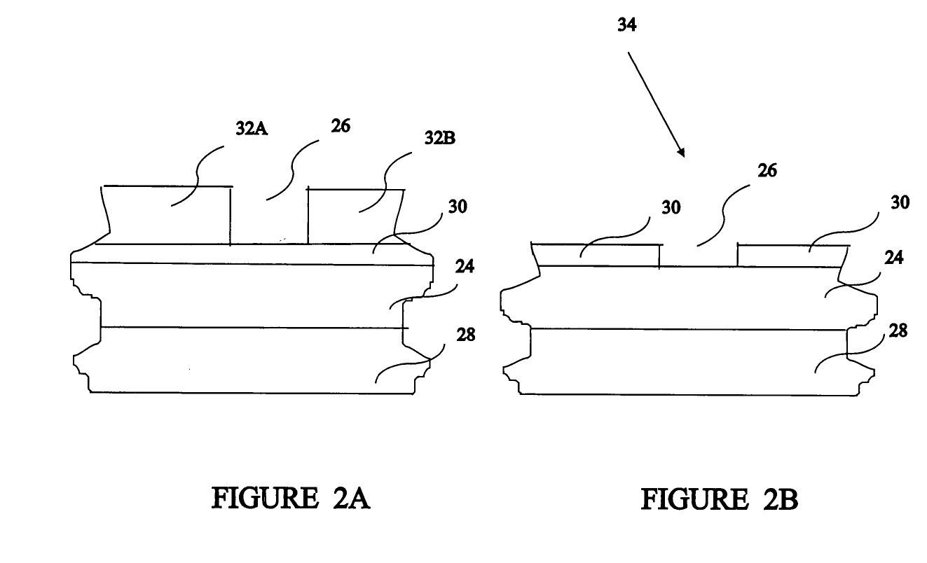

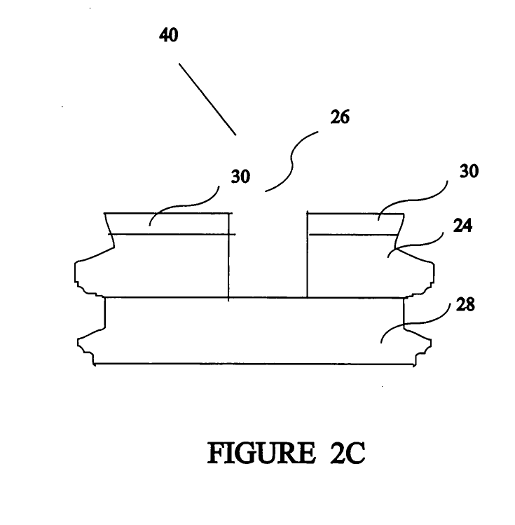

FIG. 2A is a section view of a semiconductor structure before the first etching process of the present invention. In this Figure, a via etching layer structure is created by placing in a chamber (not shown in Figure) the semiconductor substrate 28. The semiconductor substrate 28 comprises a polymer layer 24 deposited on the semiconductor substrate 28, a hard-mask 30 deposited on the polymer layer 24, and a photoresist mask 32 deposited on the hard-mask 30.

FIG. 2B is a section view of a semiconductor structure after the first etching process of the present invention. A hard-mask opening process 34 on the FIG. 2A structure. During hard-mask opening process 34, a first fluoride gas is released into the chamber, whereby an exposed portion of the hard-mask 30 defining a via hole 26 is etched away. In the preferred embodiment, the chamber is a Trikon Omega 201 Inductively Coupled Plasma (ICP) machine. In this embodiment, first fluoride gas comprises equal amounts of trifluoromethane (CHF₃) and argon (Ar). The bias power is applied through a wafer chuck to the semiconductor structure. Preferably, the semiconductor structure is a semiconductor substrate. Hard-mask opening process 34 further includes applying bias power for a 4 inch radius semiconductor substrate within a range of approximately 20 Watts to approximately 60 Watts within a preferred range of approximately 25 Watts to approximately 32 Watts. For other radius semiconductor substrates, applied bias power scales to maintain the above described ratio of Watts to surface area of the semiconductor wafer. Afterwards, hard-mask opening process 34 further includes applying pulse-modulated power comprising inductively coupled plasma power from a machine such as Trikon Omega 201 Inductively Coupled Plasma (ICP) machine. The applied pulse modulated power to the semiconductor substrate is within a range of approximately 450 Watts to approximately 900 Watts with a preferred range of approximately 725 Watts to approximately 755 Watts. Additionally, hard-mask opening process 34 includes pressurizing within a range of approximately 5 milli-Torr to approximately 20 milli-Torr with the preferred pressure of approximately 10 milli-Torr. To complete the first etching process, hard-mask opening process 34 does all the above steps for approximately three to seven minutes.

The FIG. 2C is a sideview semiconductor structure resulting from performing a second etching process on the FIG. 2B structure. During polymer etching process 40, a second fluoride gas is released into the chamber, whereby an exposed portion of the polymer layer 24 defining the via hole 26 is etched away, thus creating the via hole 26 with vertical sidewalls. Second fluoride gas comprises Sulfur Hexafluoride (SF₆) and Oxygen (O₂). Preferably, second fluoride gas comprising Sulfur Hexafluoride (SF₆) and Oxygen (O₂), wherein the volume ratio of gases is 1 part (SF₆) to 3 parts (O₂). During the polymer layer etching process 40, a bias power and a pulse-modulated power are applied to the semiconductor substrate 28. Preferably, the polymer layer etching process 40 further includes applying bias power to a 4 inch radius semiconductor substrate within a range of approximately 40 Watts to approximately 100 Watts with the preferred range of approximately 55 Watts to approximately 62 Watts. For other radius semiconductor substrates, applied bias power scales to maintain the above described ratio of Watts to surface area of the semiconductor wafer. Furthermore, preferably applying pulse-modulated power comprising inductively coupled plasma power from an Trikon Omega 201 ICP within a range of approximately 400 Watts to approximately 750 Watts with the preferred range of approximately 475 to approximately 505 Watts. Finally, polymer layer etching process 40 includes pressurizing the chamber the preferred range of approximately 1 milli-Torr to approximately 7 milli-Torr with the preferred pressure of approximately 5 milli-Torr. To complete the second etching process, polymer layer etching process 40 steps above continue for approximately one and half minutes to approximately six minutes.

The addition of the first fluoride gas and the second fluoride gas to the chamber produces the unexpected results of achieving the vertical sidewalls for the via-hole of the present invention. In contrast, prior etching process utilizing only SF₆, i.e., the second fluoride gas, did not achieve the present invention via-hole vertical sidewalls.

In this embodiment, hard-mask 30 is Silicon Dioxide (SiO₂) and polymer layer 24 is Benzocyclobutene (BCB) polymer. In the alternative embodiment, polymer layer 24 is a material with a dielectric constant less than 3 that etches at a rate greater than 10 times faster than that of the hard-mask. The semiconductor substrate is a compound material such as Indium Phosphide (InP), Gallium Arsenide (GaAs), and generally III-V semiconductor compound materials.

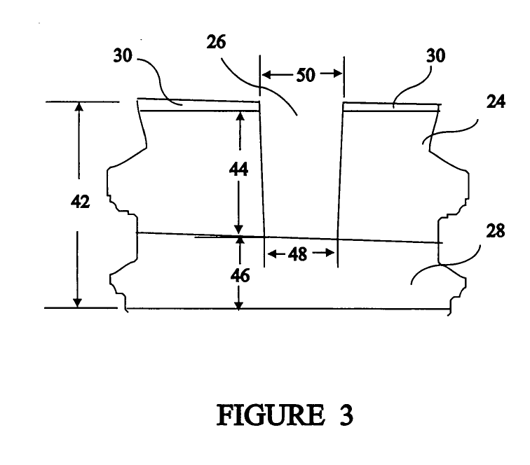

FIG. 3 is a section view of the present inventive hard-mask opening process 34 and polymer etching process 40. In this embodiment of the present invention, the hard-mask opening process includes for approximately three to seven minutes doing the following steps including: applying a first fluoride gas comprising an equal ratio of trifluoromethane (CHF₃) and argon (Ar) with an associated pressure of approximately 10 milli-Torr, applying a temperature of approximately 20 degrees C., applying pulse-modulated power comprising inductively coupled plasma power from a Trikon Omega 201 ICP within a range of approximately 725 Watts to approximately 755 Watts, applying bias power to the 4 inch radius semiconductor substrate comprising a bias power with a range of approximately 25 Watts to approximately 32 Watts, and completing the process within a range of approximately one and half minutes to six minutes.

In FIG. 3, the via hole created has the following dimensions: via-opening width 50 was 1.66 microns (μm), a via depth 44 of 3.17 μm, the remainder after dry etch processing of a hard-mask 30 was 0.44 μm, distance 46 from the bottom of the via hole to the substrate is 3.03 μm, and distance of the bottom of the via hole 48 is 1.32 μm. Via hole aspect ratio, i.e., ratio of via depth to via-opening width 50 can be achieved within the preferred range of values greater than 4 to 1, where via-opening width 50 is 4 times smaller than the via depth 44. However, in an alternative embodiment of the present invention, a via-opening width 50 may selected within a preferred range of 0.4 μm to 2.0 μm, a via depth may be selected within a preferred range of 2.0 μm to 6.0 μm, the remainder after dry etch processing of hard-mask 30 may be selected within a preferred range of 0.20 μm to 0.6 μm, distance 46 from the bottom of the via hole to the substrate may be selected within a preferred range of 3.0 μm to 5.0 μm, and distance of the bottom of the via hole 48 may be selected within a preferred range of 0.3 μm to 1.8 μm.

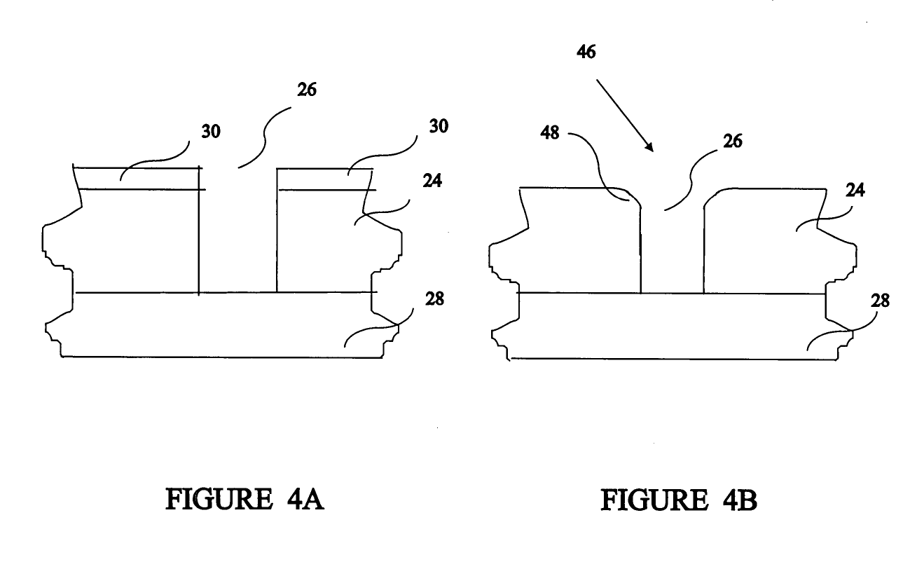

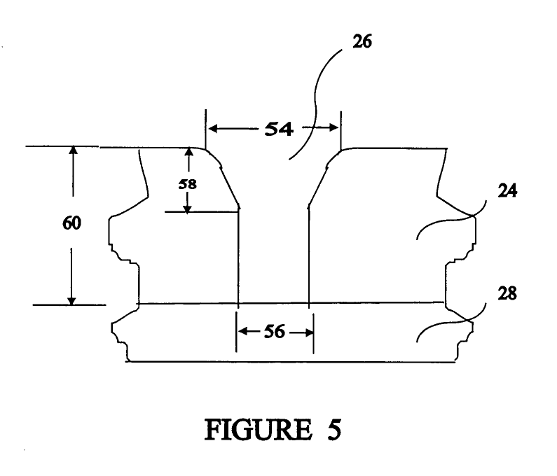

FIG. 4A is a section view of a semiconductor structure by the first and the second etching processes of the present invention before beginning the third etching process of the present invention. Initially, a semiconductor substrate 28 including a polymer layer 24 defining a sub-micron wide via-opening deposited on the semiconductor substrate 28, and a hard-mask 30 defining the sub-micron wide via-opening deposited on polymer layer 24 is placed in a chamber.

FIG. 4B is a section view of a semiconductor structure after the third etching process of the present invention. During a hard-mask removal and tapered via etching process 46, a third fluoride gas is released into the chamber, whereby hard-mask 30 is etched away, and whereby an exposed portion of polymer layer 24 proximal to the sub-micron wide via-opening is etched away to create tapered sidewalls. Third fluoride gas comprises trifluoromethane (CHF₃) and argon (Ar). Preferably, third fluoride gas comprises equal amounts of trifluoromethane (CHF₃) and argon (Ar). Afterwards, hard-mask and tapered via etching process 46 further includes applying bias power to a 4 inch semiconductor wafer within a range of approximately 60 Watts to approximately 200 Watts with the preferred range of approximately 105 Watts to approximately 120 Watts, applying pulse-modulated power comprising inductively coupled plasma power from an ICP machine, such as Trikon Omega 201 ICP, within a range of approximately 700 Watts to approximately 1000 Watts with the preferred range of approximately 725 Watts to approximately 755 Watts. Further, pressurizing the chamber within a range of 5 milli-Torr to 20 milli-Torr with the preferred pressure of approximately 10 milli-Torr. Hard-mask and the tapered via etching process 46 above mentioned steps continue for approximately three to four minutes to complete the third etching process to achieve hard-mask removal and tapered via hole.

The addition of the third fluoride gas for the third etching process to the chamber produces the unexpected results of allowing both hard-mask removal and tapered via etch formation. In contrast, prior wet etching process did not produce the tapered via hole of the present invention.

Preferably, hard-mask 30 is (SiO₂) and polymer layer 24 is benzocyclobutene (BCB) polymer. In the alternative, polymer layer is a material with a dielectric constant less than 3 and has an etch rate 10 times slower than that of the hard-mask. Furthermore, the ratio of the tapered sidewalls to non-tapered sidewalls is less than one-third. In this embodiment, the aspect ratio of a depth of the via hole compared to the width of the via-opening is a ratio greater than 2 to 1.

FIG. 5 is a section view of the third etching process. In this example, the hard-mask removal and the tapered via etching process 46 includes for approximately three to four minutes doing all the following steps: applying a third fluoride gas 47 comprising an equal ratio of trifluoromethane (CHF₃) and argon (Ar) with an associated pressure of approximately 10 milli-Torr, applying temperature of approximately 20 degrees C., applying pulse-modulated power comprising inductively coupled plasma power from an ICP machine, such as a Trikon Omega 201 ICP, with the preferred range of approximately 725 Watts to approximately 755 Watts, and applying bias power within a preferred range of approximately 105 Watts to approximately 120 Watts.

For this example, a sub-micron via-opening 54 is 1.0 μm, a depth 60 of 2.0 μm, the distance of bottom of the via hole 56 is 0.5 μm and the length of the tapered portion of via 58 is with the approximate range of one-third to one-half the depth of the via 60. Via hole aspect ratios can be achieved within one preferred range of values greater than 2 to 1, where via-opening 54 may be 2 times smaller than the via depth 60. However, a via-opening width 54 may be within a preferred range of 0.80 μm to 1.20 μm, a via depth may be selected within a preferred range of 1.0 μm to 4.0 μm, and hard-mask 30 may be selected within a preferred range selected from 0.25 μm to 1.0 μm.

Furthermore, the two vias processes may be used in series. For example, the process described in FIGS. 2A-3 may be performed first to produce vertical side wall via holes and the process described in FIGS. 4A and 4B may be performed second with the same chamber to produce a via hole which has vertical sides with tapering proximal to the via-opening.

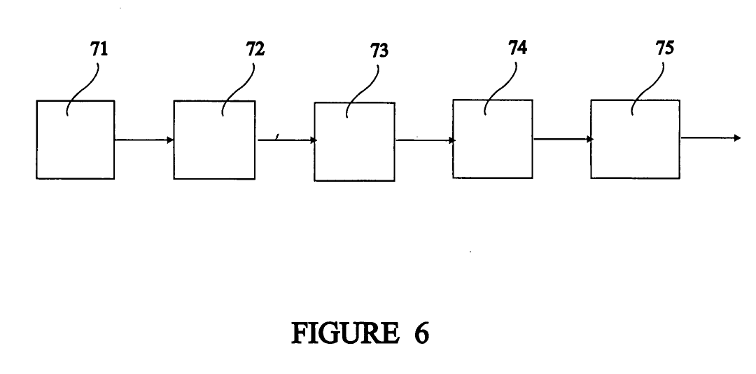

FIG. 6 a flow chart for the present invention polymer etching process. In step 71, a hard mask 30 is deposited on said polymer layer. In step 72, a photoresist mask is deposited on said hard-mask 30. In step 73, releasing a first fluoride gas into a chamber to etch a hard-mask opening for defining a via-hole opening. Within step 73, applying pulse modulated power, bias power, temperature and pressure as described in paragraphs [0023] through [0024]. In step 74, releasing a second fluoride gas into said chamber to etch said polymer layer defining said via hole. Within step 74, applying pulse modulated power, bias power, temperature, and pressure as described above in paragraphs [0025] through [0027]. In step 75, releasing a third fluoride gas into said chamber for hard-mask removal and tapering. Within step 75, applying pulse modulated power, bias power, temperature, and pressure as described above in paragraphs [0030] through [0033].

Information as herein shown and described in detail is fully capable of attaining the above-described object of the invention and the present embodiment of the invention, and is, thus, representative of the subject matter which is broadly contemplated by the present invention. The scope of the present invention fully encompasses other embodiments which may become obvious to those skilled in the art, and is to be limited, accordingly, by nothing other than the appended claims, wherein reference to an element in the singular is not intended to mean “one and only one” unless explicitly so stated, but rather “one or more.” All structural and functional equivalents to the elements of the above-described embodiment and additional embodiments that are known to those of ordinary skill in the art are hereby expressly incorporated by reference and are intended to be encompassed by the present claims.

Moreover, no requirement exists for a device or method to address each and every problem sought to be resolved by the present invention, for such to be encompassed by the present claims. Furthermore, no element, component, or method step in the present disclosure is intended to be dedicated to the public regardless of whether the element, component, or method step is explicitly recited in the claims. However, one skilled in the art should recognize that various changes and modifications in form and material details may be made without departing from the spirit and scope of the inventiveness as set forth in the appended claims. No claim herein is to be construed under the provisions of 35 U.S.C. § 112, sixth paragraph, unless the element is expressly recited using the phrase “means for.”

### INDUSTRIAL APPLICABILITY

The present invention applies industrially to a dry etching process for semiconductor substrates. More particularly, the present invention applies industrially to a polymer dry etching process that produces smaller dimensionally accurate via holes for a thick polymer layer in a semiconductor substrate. The process maintains adjacent device features and reduces semiconductor wafer substrate cycle time through the reduction of processing steps.

1. A via etching process for a polymer layer deposited on a semiconductor substrate comprising said steps of:
placing a hard-mask on said polymer layer;
placing a photoresist mask on said hard-mask;
releasing a first fluoride gas into a chamber to etch a hard-mask opening for defining said via hole; and
releasing a second fluoride gas into said chamber to etch an exposed portion of said polymer layer defining said via hole with vertical sidewalls.

2. A via etching process as recited in claim 1, wherein said first fluoride gas comprises trifluoromethane and argon.

3. A via etching process as recited in claim 1, wherein said first fluoride gas comprises a volume ratio of one part trifluoromethane to one part argon.

4. A via etching process as recited in claim 1, wherein said step of releasing first fluoride gas further includes applying bias power within the range of approximately 25 Watts to approximately 32 Watts.

5. A via etching process as recited in claim 1, wherein said step of releasing first fluoride gas further includes applying pulse-modulated power comprising inductively coupled plasma power within the range of approximately 725 Watts to approximately 755 Watts.

6. A via etching process as recited in claim 1, wherein said said step of releasing first fluoride gas further includes for approximately three to seven minutes doing all the following: applying a first fluoride gas comprising an equal ratio of trifluoromethane and argon, applying a pressure of approximately 10 milli-Torr, applying a temperature of approximately 20 degrees C., applying pulse-modulated power comprising inductively coupled plasma power within the range of approximately 725 Watts to approximately 755 Watts, and applying bias power within the range of approximately 25 Watts to approximately 32 Watts.

7. A via etching process as recited in claim 1, wherein said second fluoride gas comprises Sulfur Hexafluoride and Oxygen.

8. A via etching process as recited in claim 1, wherein said second fluoride gas comprises Sulfur Hexafluoride and Oxygen, wherein said volume ratio of gases is 1 part Sulfur Hexafluoride to 3 parts Oxygen.

9. A via etching process as recited in claim 1, wherein said polymer layer etching step further comprises applying bias power within the range of approximately 57 Watts to approximately 62 Watts.

10. A via etching process as recited in claim 1, wherein step of releasing a second fluoride gas further includes applying pulse-modulated power comprising inductively coupled plasma power within the range of approximately 475 Watts to approximately 505 Watts.

11. A via etching process as recited in claim 1, wherein step of releasing a second fluoride gas further includes for approximately one and half minutes to six minutes doing all the following: applying a second fluoride gas comprising Sulfur Hexafluoride and Oxygen, wherein said ratio of gases is 1 part Sulfur Hexafluoride to 3 parts Oxygen with an associated pressure of approximately 5 milli-Torr, applying temperature of approximately 20 degrees C., applying pulse-modulated power comprising inductively coupled plasma power with the range of approximately 475 Watts to approximately 505 Watts, and applying bias power comprising a bias power with the range of approximately 25 Watts to approximately 32 Watts.

12. A via etching process as recited in claim 1, wherein said polymer layer is benzocyclobutene polymer.

13. A via etching process as recited in claim 1, wherein said polymer layer is a material with a dielectric constant less than 3.

14. An etch process as recited in claim 1, wherein said semiconductor substrate is chosen from the group consisting of Indium Phosphide and Gallium Arsenide.

15. A via etching process for a polymer layer on a semiconductor substrate comprising the steps of:
placing in a chamber said semiconductor substrate including a polymer layer defining a sub-micron wide via-opening deposited on said semiconductor substrate, and a hard-mask defining said sub-micron wide via-opening deposited on said polymer layer;
releasing a third fluoride gas into said chamber;
applying bias power within the range of approximately 105 Watts to approximately 120 Watts;
applying pulse-modulated power within the range of approximately 725 Watts to approximately 755 Watts;
pressurizing said third fluoride gas within a range of approximately 5 milli-Torr to approximately 20 milli-Torr; and
continuing the above steps until etching said hard-mark and an exposed portion of said polymer layer proximal to said sub-micron wide via-opening creating tapered sidewalls.

16. A via etching process as recited in claim 15, wherein said third fluoride gas comprises trifluoromethane and argon.

17. A via etching process as recited in claim 15, wherein said third fluoride gas comprises a volume ratio of one part trifluoromethane to one part argon.

18. A via etching process as recited in claim 15, wherein said continuing the above steps within the range of approximately three minutes to approximately seven minutes.

19. A via etching process as recited in claim 15, wherein said polymer layer is benzocyclobutene polymer.

20. A via etching process as recited in claim 15, wherein said polymer layer is a material with a dielectric constant less than 3 and has an etch rate 10 times slower than that of said hard-mask layer.

21. A device including a via produced by the process comprising the steps of:
placing a hard-mask on said polymer layer;
placing a photoresist mask on said hard-mask;
releasing a first fluoride gas into a chamber to etch a hard-mask opening for defining said via hole; and
releasing a second fluoride gas into said chamber to etch an exposed portion of said polymer layer defining said via hole with vertical sidewalls.

22. A device including a via produced by the process comprising the steps of:
placing in a chamber said semiconductor substrate including a polymer layer defining a sub-micron wide via-opening deposited on said semiconductor substrate, and a hard-mask defining said sub-micron wide via-opening deposited on said polymer layer;
releasing a third fluoride gas into said chamber;
applying bias power within the range of approximately 105 Watts to approximately 120 Watts;
applying pulse-modulated power within the range of approximately 725 Watts to approximately 755 Watts;
pressurizing said third fluoride gas within a range of approximately 5 milli-Torr to approximately 20 milli-Torr; and
continuing the above steps until etching said hard-mark and an exposed portion of said polymer layer proximal to said sub-micron wide via-opening creating tapered sidewalls.
